(19) United States
(12) Patent Application Publication
(10) Pub. No.: US 2008/0012113 A1
(43) Pub. Date: Jan. 17, 2008

(54) Carrier module and test tray for an upright-positionable packaged chip, and testing method

(75) Inventor: Hae Jun Park, Asan-si (KR)

Correspondence Address: KED & ASSOCIATES, LLP, P.O. Box 221200, Chantilly, VA, 20153-1200, US

(73) Assignee: Mirae Corporation

(21) Appl. No.: 11/826,356

(22) Filed: Jul. 13, 2007

(30) Foreign Application Priority Data
Jul. 14, 2006 (KR) 10-2006-0066361

(51) Int. Cl. H01L 23/02

(52) U.S. Cl. 257/686

(57) ABSTRACT

A carrier module for a test tray includes a main body having an insertion slot that passes through the main body. An upright-positionable packaged chip can be inserted into the insertion slot, and a holding unit, provided on the main body holds and releases the upright-positionable packaged chip. The upright positionable packaged chip is held in a position where electrical contacts on the chip package are exposed from the main body so that the chip package can be tested.

### BACKGROUND

1. Field

The present application discloses a carrier module and a test tray for upright-positionable packaged semiconductor chips, and a testing method for upright-positionable packaged chips.

2. Background

A memory card or flash memory card is a solid-state electronic flash memory data storage device used with digital cameras, handheld and laptop computers, telephones, music players, video game consoles, and other consumer electronics. They offer high re-recordability, power-free storage, small form factor, and rugged environmental specifications. Flash memory cards have also been suggested as a possible replacement for the floppy disk or CDs and DVDs, although USB flash memory drives, which work on almost any computer with a USB port, have been filling this role instead.

A flash memory card includes one or more semiconductor memory chips packaged into a housing. Electrical connecting pins formed on one or more sides of the housing. This type of a packaged chip, with electrical contacts formed on at least one side of the housing, is hereinafter referred to as “an upright-positionable packaged chip”. A memory stick, which has electrical contacts exposed on one surface of its housing, is among the upright-positionable packaged chips.

At the conclusion of a packaging process, the upright-positionable packaged chips are put through a series of environmental, electrical, and reliability tests. These tests vary in type and specifications, depending on the customer and use of the upright-positionable packaged chips. Typically, the upright-positionable packaged chips are manually tested, meaning an individual inserts the packed chips into a test socket, and then removes the chip packages after testing is completed. Such manual testing tends to be quite slow compared to the automated testing performed on other types of memory chips.

To solve this problem, a handler is under development, which automatically tests the upright-positionable packaged chips. Such handlers will be capable of performing automated tests at high and low temperatures. The handler will use a tray equipped with carrier modules, into which a plurality of the upright-positionable packaged chips can be inserted. The trays with the carrier modules and inserted chips will then be used to perform speedy testing for various characteristics.

However, the upright-positionable packaged chip is different in form from a general type of the packaged chip, with typically has a quadrilateral housing and two parallel rows of electrical connecting pins, usually protruding from the longer sides of the package and bent downward. The trays and carrier modules for the general type of the packaged chip cannot be used on the new handler for testing upright-positionable packaged chips.

### BRIEF DESCRIPTION OF THE DRAWINGS

The embodiments will be described in detail with reference to the following drawings, in which like reference numerals refer to like elements, and wherein:

FIG. 1 shows a perspective view illustrating a structure of a carrier module for an upright positionable packaged chip;

FIG. 2 is a cross-sectional view illustrating a principle part of the carrier module of FIG. 1;

FIG. 3 is a cross-sectional view illustrating operation of the carrier module of FIG. 1;

FIG. 4 is a cross-sectional view illustrating an alternate embodiment of a carrier module for an upright-positionable packaged chip;

FIG. 5 is a cross-sectional view illustrating operation of the carrier module of FIG. 4;

FIG. 6 illustrates a test tray having a plurality of carrier modules for upright-positionable packaged chip installed thereon; and

FIG. 7 is a flow chart showing a method of testing a plurality of upright-positionable packaged chips using the illustrated carrier modules and test trays.

### DETAILED DESCRIPTION

Reference will now be made in detail to the preferred embodiments of the present invention, examples of which are illustrated in the accompanying drawings.

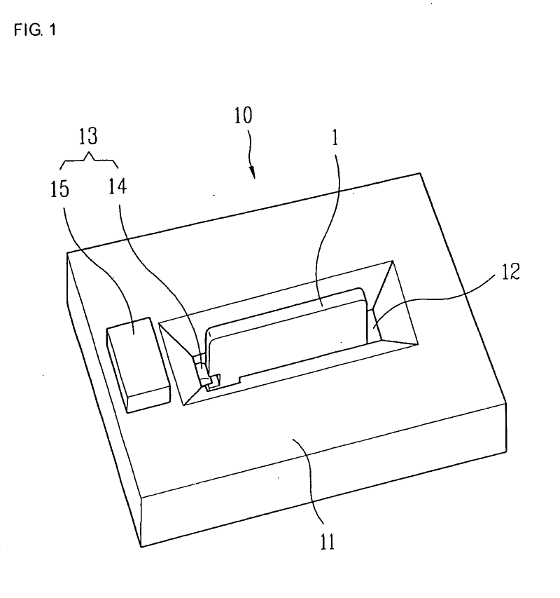

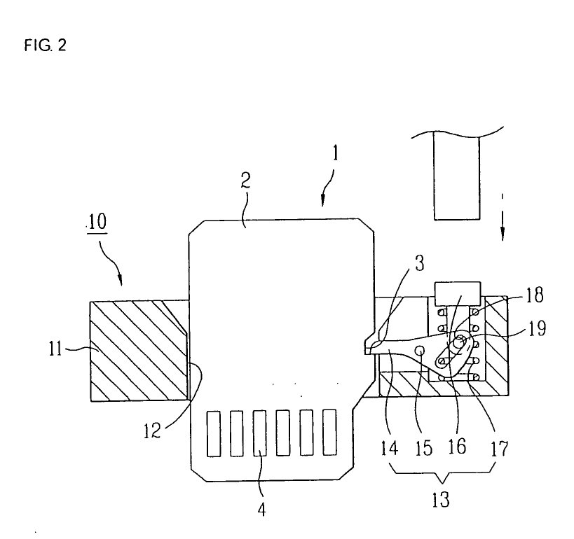

As shown in FIGS. 1 and 2, an upright-positionable packaged chip 1 has electrical contacts 4 exposed on at least one external surface of its housing. The upright-positionable packaged chip 1 may include a rectangular or square housing 2. A groove 3 is formed on one side of the housing 2. The electrical contacts 4, which are configured to connect to a built-in slot of various electronic devices, are made of conductive material. The upright-positionable packaged chips may include any type of packaged chips which can be positioned in the upright position, regardless of pin or contact shapes, such as a packaged chips with electrical contacts on one side of a quadrilateral housing.

The carrier module 10 includes a quadrilateral main body 11 having an insertion slot 12 pierced through the center thereof. A holding unit 13 acts to hold a upright-positionable packaged chip 1 which is inserted into the insertion slot 12. An inlet of the insertion slot 12 may be angled or funnel-shaped for easily inserting the upright-positionable packaged chip 1.

The holding unit 13 includes a latch 14, which in this embodiment is rotatable about a horizontal axis of a bar 15 provided on one side of the insertion slot 12. A pushing lever 16 is provided adjacent to the latch 14, such that it is movable moveable vertically. A pin 19 protrudes from the lower part of the pushing lever 16, and the pin 19 is inserted into a guide hole 18 formed obliquely on a lower part of the latch 14. A coil spring 17 elastically supports the pushing lever 16.

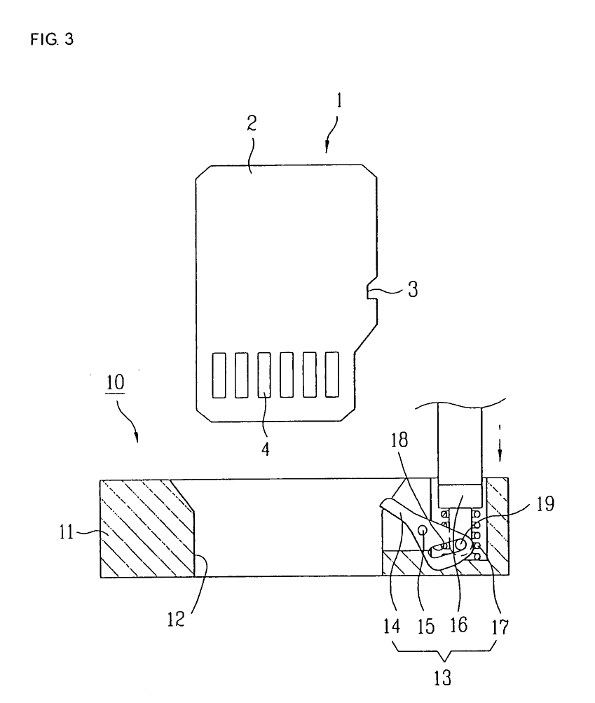

Operation of the carrier module 10 will now be described. The coil spring 17 pushes the pushing lever 16 upward. When a load is not applied to the pushing lever 16, the pushing lever 16 and the latch 14 are positioned as shown in FIG. 2. The pushing lever 16, as shown FIG. 3, is moved downwards when a load is applied to the pushing lever 16. The pin 19 of the pushing lever 16 is moved within the guide hole 18 of the latch 14, when the pushing lever 16 is moved down, which causes the latch 14 to move upward to open the insertion slot 12. This allows an upright-positionable packaged chip to be removed from the insertion slot.

The upright-positionable packaged chip 1, oriented in the upright position, is inserted into the insertion slot 12. When the upright-positionable packaged chip 1 is inserted into the insertion slot 12, the side edge of the chip 1 bears against the latch 14, which rotates the latch 14 downward. When the chip 1 is fully inserted, as shown in FIG. 2, the latch settles in the groove 3 formed on the side edge of the chip 1 to hold the packaged chip in the carrier module. In addition, when the packaged chip 1 is fully inserted, the electrical contacts 4 of the upright-positionable packaged chip 1 remain exposed so that they can be connected to corresponding contacts of a testing socket.

The pushing lever 16 is pushed to release the latch 14 from the groove 3, so that the upright-positionable packaged chip 1 can be removed from the carrier module 10. That is, when the pushing lever 16 is pushed, the latch 14 is rotated to the position shown in FIG. 3, and the latch 14 is removed from the groove 3. This enables the upright-positionable packaged chip 1 to be drawn out from the carrier module 10.

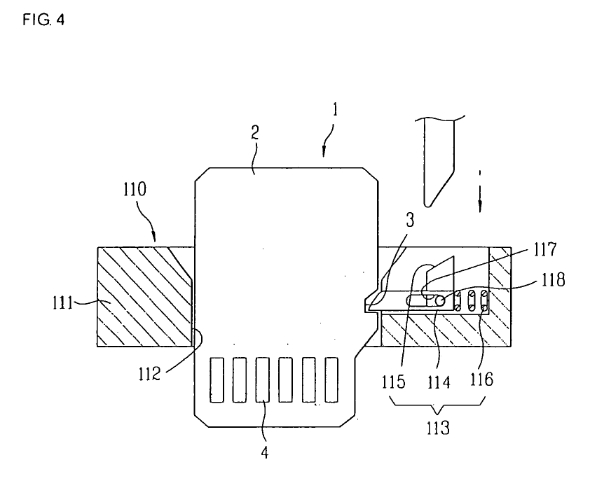

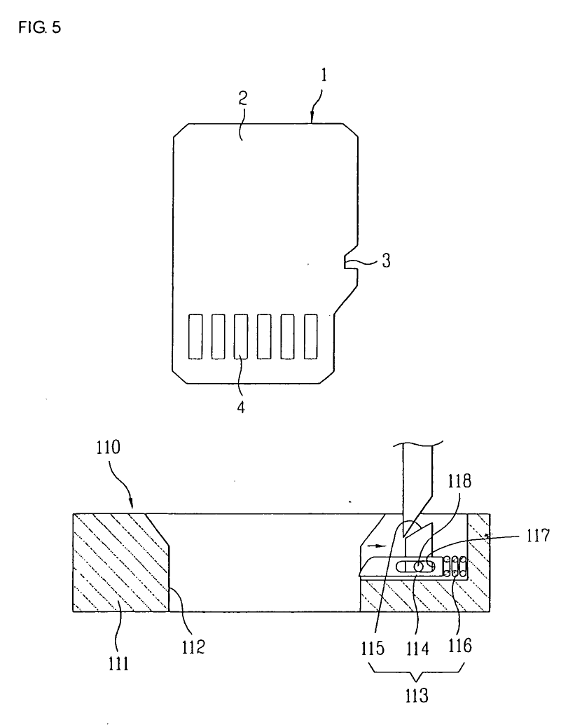

In this first embodiment, rotation of the latch 14 enables the upright-positionable packaged chip 1 to be held in place in the insertion slot or to be drawn out from t h e insertion slot. However, alternate embodiments of the carrier module may have a structure in which the latch 14 is horizontally moved into the groove 3 to hold the upright-positionable packaged chip 1 in place. A carrier module 110 according to such a second another embodiment is shown in FIGS. 4 and 5.

In this embodiment, a latch 114 is provided on the carrier module 110 such that it is horizontally movable in a direction perpendicular to an insertion/removal direction of the upright-positionable packaged chip. A coil spring 116 is provided behind the latch 114, to elastically support the latch 114.

A stopper 118 is formed on a lower part of a pushing lever 115. An upper surface of the pushing lever 115 is inclined. The stopper 118 limits linear motion of the latch 114. A guide hole 117 is formed on the latch 114. The latch 114 is connected to the pushing lever 115 by inserting the stopper 118 into the guide hole 117. In alternate embodiments, the latch 114 and the pushing lever -115 may be formed as one piece.

As shown in FIG. 5. when the pushing lever 115 is pushed from over the carrier module 110, the latch 114 is moved backwards to open the insertion slot 112. When a chip 1 is inserted into the slot 12, the side edge of the chip 1 will initially push the latch 114 backwards against the force of the spring 116. When the groove is even with the latch 114, the spring 116 will push the latch 114 into the groove 3. When the latch 114 is inserted into the groove 3 of the upright-positionable packaged chip 1, the upright-positionable packaged chip 1 is held in place in the insertion slot of the carrier module 110.

When an opening pushing device contacts the top surface of the of the pushing lever 115, and then moved further downward, the inclined surface will cause the pushing lever to move to the right, as shown in FIG. 5. This removes the latch 114 from the groove on the upright-positionable packaged chip, so that the packaged chip can be removed from the insertion slot.

The holding unit for the carrier module is not limited to the two embodiments described above. A variety of different structures in which the upright-positionable packaged chip is held in place in and drawn out from the carrier module can be used.

A plurality of carrier modules will be arranged at regular intervals in columns and rows on test trays, as is well known in the art. Test handler machines then make use of the test trays, which each have a plurality of carrier modules, to conduct electrical tests on the upright-positionable packaged chips.

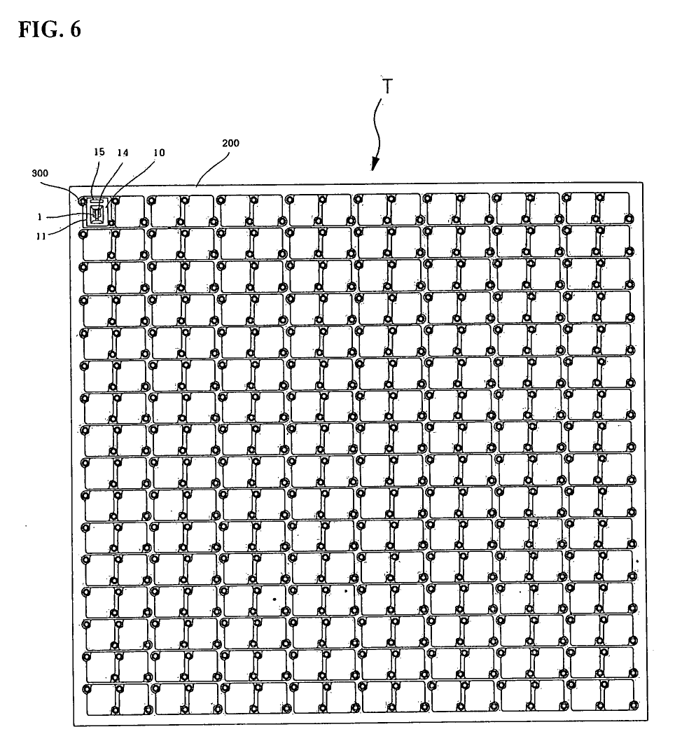

FIG. 6 illustrates one embodiment of a test tray having a plurality of carrier modules for upright-positionable packaged chips mounted thereon. As shown in FIG. 6, the test tray T includes a frame 20, upon which a plurality of carrier modules for upright-positionable chips are mounted. Each of the carrier modules 10 is mounted on the test tray T with two or more connecting members 300. The connecting members 300 may include an elastic member, such as a spring. The elastic member of the connecting members will allow the carrier modules and the chips they hold to move slightly with respect to the test tray T. This helps to ensure that the chips are not damaged as they are brought into contact with sockets of testing modules.

In FIG. 6, to aid clarity, the details of only one carrier module 10 is depicted. However, in reality, there would be a carrier module 10 for an upright-positionable chip at each of the square mounting positions of the test tray T shown in FIG. 6.

A test tray with carrier modules for upright-positionable packaged chips can accommodate even more chips than a test tray with carrier modules for traditional shaped packaged chips. For example, a test tray as described above is capable of accommodating more than 1,000 upright-positionable packaged chips, whereas a conventional test tray can only accommodate 256 packaged chips.

The carrier modules described above hold the upright-positionable packaged chip in place in the insertion slot of the carrier module, with the electrical contacts exposed. This makes it easier to connect the electrical contacts to the slot of the tester.

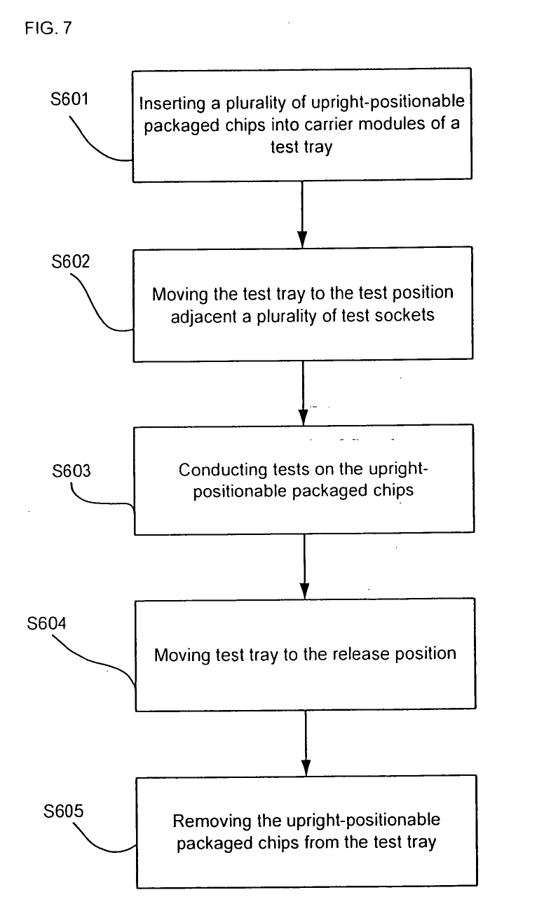

A method of testing a plurality of upright-positionable packaged chips is illustrated in FIG. 7. As shown therein, in a first step S601 a plurality of upright-positionable packaged chips would be inserted into a corresponding plurality of carrier modules which are mounted on a test tray. In step S602 the test tray is then moved to a test position adjacent a plurality of test sockets. The electrical contacts on the upright-positionable packaged chips would be exposed beneath the lower the surface of the carrier modules of the test tray. As a result, it is possible for the electrical contacts on the packaged chips to directly interact with corresponding electrical contacts on test sockets.

In step S603 the test sockets would be used to conduct a plurality of tests on the upright-positionable packaged chips mounted on the test tray. These tests could be conducted at regular room temperature, or the testing could be conducted in temperature controlled environmental chambers where the testing is performed at elevated or lowered temperatures.

Once the testing is complete, in step S604, the test tray would be removed to a release position. As the release position, the latches of the plurality of carrier modules would be moved to the release position and the upright-positionable packaged chips within the carrier modules would be removed from the test tray. Typically, new, untested upright-positionable packaged chips would then be inserted into the test tray so that another set of tests could be performed.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalents of such metes and bounds are therefore intended to be embraced by the appended claims.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although a number of illustrative embodiments have been described, it should be understood that numerous other modifications and embodiments can be devised by those skilled in the art that will fall within the spirit and scope of the principles of this disclosure. More particularly, various variations and modifications are possible in the component parts and/or arrangements that would fall within the scope of the disclosure, the drawings and the appended claims. In addition to variations and modifications in the component parts and/or arrangements, alternative uses will also be apparent to those skilled in the art.

What is claimed is:

1. A carrier module, comprising:
a main body having an insertion slot that passes therethrough, wherein the insertion slot is configured to receive an upright-positionable packaged chip, and
a holding unit mounted on the main body, wherein the holding unit holds and releases an upright-positionable packaged chip that is inserted into the insertion slot.

2. The carrier module according to claim 1, wherein the holding unit includes a latch that interacts with a groove formed on a side of an upright-positionable packaged chip that is inserted into the insertion slot.

3. The carrier module according to claim 2, wherein the latch can be inserted into the groove of an upright-positionable packaged chip located in the insertion slot to hold the upright-positionable packaged chip in place.

4. The carrier module according to claim 2, wherein the latch moves between a first position where it is inserted into the groove and a second position where it is removed from the groove.

5. The carrier module according to claim 4, wherein the holding unit further comprises a pushing lever that is coupled to the latch, wherein the pushing lever is movable by an outside force, and wherein movement of the pushing lever causes the latch to move between the first and second positions.

6. The carrier module according to claim 5, further comprising an elastic member elastically supporting the pushing lever.

7. The carrier module of claim 6, wherein the elastic member biases the latch into the first position.

8. The carrier module according to claim 4,-wherein the latch rotates to move between the first and second positions.

9. The carrier module according to claim 4, wherein the latch moves in a linear direction to move between the first and second positions.

10. A test tray for a test handler comprising the carrier module of claim 1.

11. The test tray of claim 10, wherein a plurality of carrier modules are mounted on the test tray.

12. A test tray equipped with a plurality of carrier modules arranged at regular intervals in columns and rows, each carrier module comprising:
a main body having an insertion slot that passes therethrough, wherein the insertion slot is configured to receive an upright-positionable packaged chip, and
a holding unit mounted on the main body, wherein the holding unit holds and releases an upright-positionable packaged chip that is inserted into the insertion slot.

13. The test tray according to claim 12, wherein the holding unit holds an upright-positionable packaged chip in the insertion slot such that electrical contacts on the packaged chip remain exposed outside of the main body.

14. A carrier module for a test tray, comprising:
a main body configured to receive an upright-positionable packaged chip such that electrical contacts on the upright-positionable packaged chip are exposed outside the main body; and
a holding unit configured to releasably hold an upright-positionable packaged chip on the main body.

15. The carrier module of claim 14, wherein the holding unit includes a latch that is configured to interact with an upright-positionable packaged chip mounted on the main body to hold the upright-positionable packaged chip on the main body.

16. The carrier module of claim 14, wherein the latch moves between a first position where the latch is inserted into a groove on an upright-positionable packaged chip mounted on the main body to hold the packaged chip on the main body, and a second position wherein the latch is withdrawn from the groove to allow the packaged chip to be removed from the main body.

17. The carrier module of claim 16, wherein an elastic member biases the latch into the first position.

18. The carrier module of claim 17, wherein insertion of an upright-positionable packaged chip into the main body causes the latch to move away from the first position against the bias of the elastic member until the latch is aligned with a groove on the upright-positionable packaged chip, and wherein the elastic member then causes the latch to move into the groove to hold the packaged chip on the main body.

19. The carrier module of claim 16, wherein the latch rotates to move between the first and second positions.

20. The carrier module of claim 19, further comprising a pushing lever that is coupled to the latch, wherein the pushing lever rotates the lever between the first and second positions.

21. The carrier module of claim 16, wherein the lever translates between the first and second positions.

22. The carrier module of claim 21, further comprising a pushing lever that is coupled to the latch, wherein the pushing lever causes the latch to translate between the first and second positions.

23. The carrier module of claim 22, wherein an end of the pushing lever has a cam surface, and wherein an opening member can interact with the cam surface of the pushing lever to cause the latch to move between the first and second positions.

24. A method of testing upright-positionable packaged chips, comprising:
inserting a plurality of upright positionable packaged chips into corresponding carrier modules of a test tray such that electrical contacts on outer surfaces of the upright-positionable packaged chips are exposed outside of the carrier modules;
moving the test tray such that the electrical contacts of the packaged chips are brought into contact with a corresponding plurality of test sockets; and
conducting tests on the packaged chips with the test sockets.
